(19) United States
(12) Patent Application Publication
(10) Pub. No.: US 2014/0232972 A1
(43) Pub. Date: Aug. 21, 2014

(54) DISPLAY SUBSTRATE, DISPLAY PANEL HAVING THE SAME AND METHOD OF MANUFACTURING THE SAME

(71) Applicant: Samsung Display Co., Ltd., Yongin-city (KR)

(72) Inventors: Dae-Cheol KIM, Hwaseong-si (KR); Dong-Kwon Kim, Asan-si (KR); Woong-Kwon Kim, Cheonan-si (KR); Ki-Hun Jeong, Cheonan-si (KR); Byeong-Hoon Cho, Seoul (KR); Kun-Wook Han, Seongnam-si (KR)

(73) Assignee: Samsung Display Co., Ltd., Yongin-city (KR)

(21) Appl. No.: 13/962,525

(22) Filed: Aug. 8, 2013

(30) Foreign Application Priority Data
Feb. 21, 2013 (KR) 10-2013-0018751

(51) Int. Cl. H01L 33/10; G02F 1/1335

(52) U.S. Cl. CPC H01L 33/10; G02F 1/133553
USPC 349/113; 438/29; 257/80

(57) ABSTRACT

A display substrate includes a base substrate, a reflection controlling layer disposed on the base substrate, and a metal wiring layer disposed on the reflection controlling layer. The metal wiring layer comprises an opaque metal. The reflection controlling layer changes wavelength-specific reflectance of reflected light using destructive interference. The reflected light is reflected from the metal wiring layer through the base substrate and the reflection controlling layer.

### CROSS REFERENCE TO RELATED APPLICATION

This application claims priority from and the benefit of Korean Patent Application No. 10-2013-0018751, filed on Feb. 21, 2013, which is hereby incorporated by reference for all purposes as if fully set forth herein.

### BACKGROUND

1. Field

Exemplary embodiments of the invention relate to a display substrate, a display panel having the display substrate, and a method of manufacturing the display substrate.

2. Description of the Background

Generally, a liquid crystal display (LCD) apparatus has various advantageous characteristics, such as thin thickness, lightweight, low power consumption, etc. Thus, the LCD is apparatus has been widely used in a monitor (e.g., television), a personal computer, a cellular phone, a laptop, an electronic pad, etc. The LCD apparatus may include an LCD panel displaying an image by using an optical transmissivity of liquid crystal and a backlight assembly disposed under the LCD panel to provide light to the LCD panel.

The LCD apparatus includes an upper substrate, a lower substrate facing the upper substrate, and a liquid crystal layer disposed between the upper substrate and the lower substrate. While metal wiring is mostly formed on the lower substrate, in some cases, the metal wiring may be formed on the upper substrate.

When the metal wiring is formed on the upper substrate, a viewer/user of the LCD apparatus may see light reflected from the metal wiring having a specific wavelength, resulting in the viewer seeing an unpleasant colored reflected light.

The above information disclosed in this Background section is only for enhancement of understanding of the background of the invention and therefore may contain information that does not form the prior art that is already known to a person of ordinary skill in the art.

### SUMMARY

One or more exemplary embodiments of the invention provide a display substrate capable of improving reflection visibility.

One or more exemplary embodiments of the invention also provide a display panel having the display substrate.

One or more exemplary embodiments of the invention also provide a method of manufacturing the display substrate.

Additional features of the invention will be set forth in the description which follows, and in part will be apparent from the description, or may be learned by practice of the invention.

Exemplary embodiments of the invention disclose a display substrate including a base substrate, a reflection controlling layer disposed on the base substrate, and a metal wiring layer disposed on the reflection controlling layer and comprising an opaque metal. The reflection controlling layer is configured to provide a reflectance of reflected light corresponding to a wavelength using destructive interference. The reflected light is reflected from the metal wiring layer through the base substrate and the reflection controlling layer.

Exemplary embodiments of the invention also disclose a display panel including an upper substrate, a lower substrate facing the upper substrate, and a liquid crystal layer disposed between the upper substrate and the lower substrate. The upper substrate includes an upper base substrate, a reflection controlling layer disposed on the upper base substrate, a metal wiring layer disposed on the reflection controlling layer, and a first insulation layer disposed on the metal wiring layer. The lower substrate includes a lower base substrate, a pixel switching element disposed on the lower base substrate, and a second insulation layer disposed on the pixel switching element. The liquid crystal layer is disposed between the first insulation layer and the second insulation layer. The reflection controlling layer is configured to provide a reflectance of reflected light corresponding to a wavelength using destructive interference. The reflected light is reflected from the metal wiring layer through the base substrate and the reflection controlling layer.

Exemplary embodiments of the invention disclose a display apparatus including a display panel and a backlight unit. The display panel includes an upper substrate, a lower is substrate facing the upper substrate, and a liquid crystal layer disposed between the upper substrate and the lower substrate. The backlight unit is configured to provide light to the display panel. The upper substrate includes an upper base substrate, a reflection controlling layer disposed on the upper base substrate, a metal wiring layer disposed on the reflection controlling layer, and a first insulation layer disposed on the metal wiring layer. The lower substrate includes a lower base substrate, a pixel switching element disposed on the lower base substrate, and a second insulation layer disposed on the pixel switching element. The liquid crystal layer is disposed between the first insulation layer and the second insulation layer. The reflection controlling layer is configured to provide a reflectance of reflected light corresponding to a wavelength using destructive interference. The reflected light is reflected from the metal wiring layer through the base substrate and the reflection controlling layer.

Exemplary embodiments of the invention also disclose a method of manufacturing a display substrate. The method includes forming a reflection controlling layer on a substrate, forming a metal layer on the reflection controlling layer, forming a metal wiring by patterning the metal layer, and forming an insulation layer on the metal wiring. The reflection controlling layer includes one of silicon nitride, silicon oxide, aluminum oxide, and titanium dioxide. If the reflection controlling layer includes the silicon nitride, a thickness of the reflection controlling layer is about 500 angstroms (Å) to 900 Å. If the reflection controlling layer includes the silicon oxide, the thickness of the reflection controlling layer is about 700 Å to 1300 Å. If the reflection controlling layer includes the aluminum oxide, the thickness of the reflection controlling layer is about 600 Å to 1200 Å. If the reflection controlling layer includes the titanium dioxide, the thickness of the reflection controlling layer is about 400 Å to 800 Å.

It is to be understood that both the foregoing general description and the is following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view illustrating a display panel according to exemplary embodiments of the invention.

FIG. 2 is a partially cross-sectional perspective view illustrating a method of sensing a subject using the display panel of FIG. 1 according to exemplary embodiments of the invention.

FIG. 3 is a cross-sectional view illustrating a display panel according to exemplary embodiments of the invention;

FIG. 4 is a cross-sectional view illustrating a display panel according to exemplary embodiments of the invention.

FIGS. 5A, 5B, 5C, and 5D are cross-sectional views illustrating a method of manufacturing a display panel according to exemplary embodiments of the invention.

FIGS. 6A, 6B, 6C, and 6D are graphs illustrating reflectance according to a wavelength of a display panel according to exemplary embodiments of the invention.

### DETAILED DESCRIPTION OF ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. It may also be understood that for the purposes of this disclosure, “at least one of X, Y, and Z” can be construed as X only, Y only, Z only, or any combination of two or more items X, Y, and Z (e.g., XYZ, XYY, YZ, ZZ).

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” is and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing exemplary embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-section illustrations that are schematic illustrations of exemplary embodiments (and intermediate structures) of the invention. As such, variations from the shapes of the illustrations as a result, for example, of manufacturing techniques and/or tolerances, are to be expected. Thus, exemplary embodiments of the invention should not be construed as limited to the particular shapes of regions illustrated herein but are to include deviations in shapes that result, for example, from manufacturing.

Hereinafter, exemplary embodiments of the invention will be explained in detail with reference to the accompanying drawings.

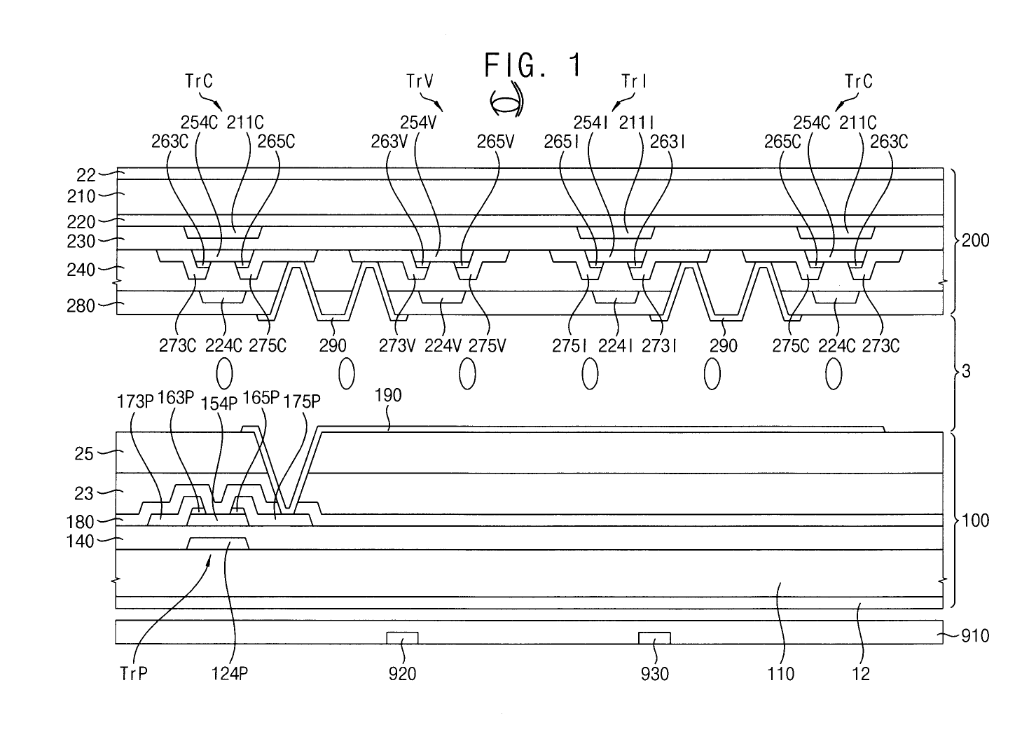

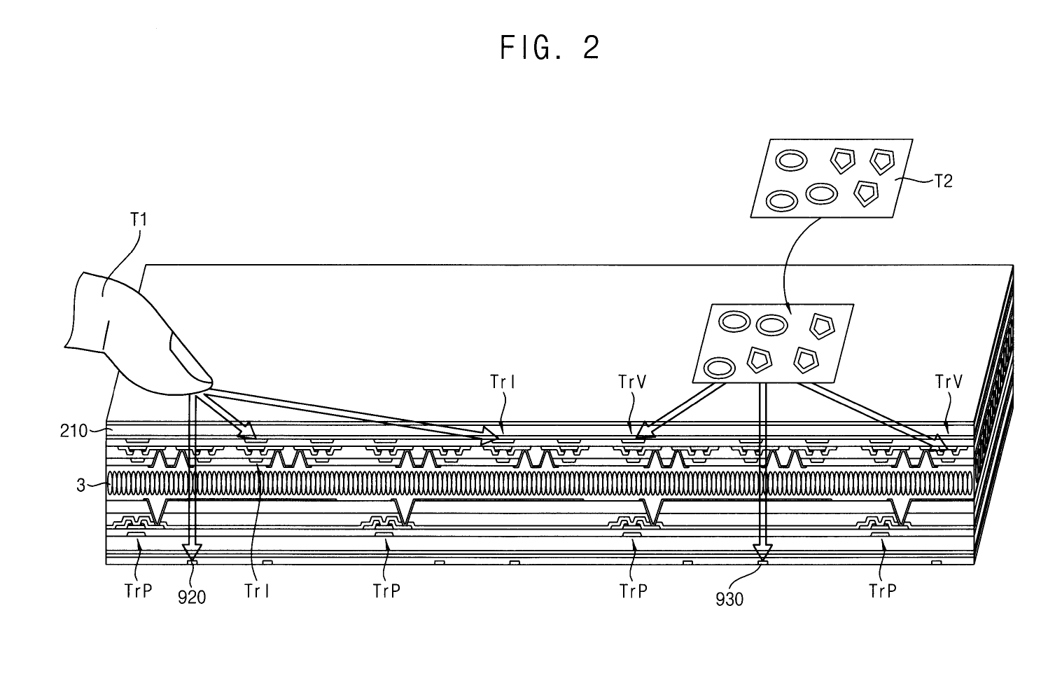

FIG. 1 is a cross-sectional view illustrating a display panel according to exemplary embodiments of the invention. FIG. 2 is a partially cross-sectional perspective view illustrating a method of sensing a subject using the display panel of FIG. 1 according to exemplary embodiments of the invention.

Referring to FIG. 1, a display panel includes a lower substrate 100 and an upper substrate 200 facing each other, and a liquid crystal layer 3 interposed between the two display substrates 100 and 200.

The liquid crystal layer 3 has negative dielectric anisotropy, and liquid crystal molecules of the liquid crystal layer 3 may be aligned such that their major axes are perpendicular to the surfaces of the two display substrates 100 and 200 when an electric field is not applied. Alignment layers (not shown) may be formed on the inner surfaces of the display substrates 100 and 200. In some cases, the alignment layers may be vertical alignment layers. Polarizers (not shown) may be provided on the outer surfaces of the display substrates 100 and 200.

The lower substrate 100 includes a lower base substrate 110 made of a transparent glass or plastic and a pixel transistor TrP disposed on the lower base substrate 110. The pixel transistor TrP includes a gate electrode 124P formed on the lower base substrate 110, a gate insulating layer 140 covering the lower base substrate 110 and the gate electrode 124P, a semiconductor layer 154P overlapping the gate electrode 124P and disposed on the gate insulating layer 140, an ohmic contact layer 163P and 165P disposed on the semiconductor layer 154P, a source electrode 173P disposed on the ohmic contact layer 163P and 165P, and a drain electrode 175P separated (e.g., spaced apart) from the source electrode 173P on the ohmic contact layer 163P and 165P.

The lower substrate 100 may further include a gate line disposed on the lower base substrate 110 and a data line intersecting the gate line. The gate line may be connected to the gate electrode 124P of the pixel transistor TrP. Also, the data line may be connected to the source electrode 173P of the pixel transistor TrP.

The lower substrate 100 may further include a passivation layer 180 covering the pixel transistor TrP, a color filter 23 disposed on the passivation layer 180, an overcoat 25 disposed on the color filter 23, and a pixel electrode 190 disposed on the overcoat 25. The pixel electrode 190 may be connected to the drain electrode 175P of the pixel transistor TrP while passing through the overcoat 25 and the passivation layer 180.

The upper substrate 200 includes an upper base substrate 210 made of transparent glass or plastic, and sensing transistors TrI and TrV. The sensing transistors TrI and TrV may include at least one infrared sensing transistor TrI and at least one visible light sensing transistor TrV. The infrared sensor TrI and the visible light sensor TrV may be uniformly formed on the whole upper substrate 200 to sense infrared rays and visible light on the whole region of the upper substrate 200. As examples, the infrared sensor TrI and the visible light sensor TrV may be alternately arranged, may be disorderly arranged, or may be arranged according to a predetermined ratio.

The upper substrate 200 may further include readout transistors TrC connected to the infrared sensing transistor TrI and the visible light sensing transistor TrV. Each readout transistor TrC may be configured to transmit a detected signal and may be disposed in the same is layer as the sensing transistors TrI and TrV.

The infrared sensing transistor TrI, the visible light sensing transistor TrV, and the readout transistor TrC may be disposed on the upper base substrate 210. In FIG. 1 and FIG. 2, the infrared sensing transistor TrI, the visible light sensing transistor TrV, and the readout transistor TrC are disposed under the upper base substrate 210. The positions of transistors TrC, TrI, and TrV may, however, vary based on a deposition sequence in manufacturing the upper substrate 200.

The infrared sensing transistor TrI may include a semiconductor layer 2541, ohmic contact layers 2631 and 2651, a source electrode 2731, a drain electrode 2751, a gate insulating layer 240, and a gate electrode 2241. The semiconductor layer 2541 may be disposed on the upper base substrate 210, and may be formed of amorphous silicon-germanium or micro-crystalline silicon. In some cases, the semiconductor layer 2541 may be made of two layers including a lower layer formed of amorphous silicon and an upper layer formed of amorphous silicon-germanium or micro-crystalline silicon. In some cases, the semiconductor layer 2541 may be made of two layers including a lower layer of micro-crystalline silicon and an upper layer of amorphous silicon-germanium.

When forming a semiconductor layer 2541 having two layers, a deposition speed may be improved compared with when forming a single layer of amorphous silicon-germanium or micro-crystalline silicon, and the lower layer formed with the channel may be covered by the upper layer, such that damage to the channel may be prevented in the manufacturing process, thereby improving characteristics such as transistor speed. The thickness of the semiconductor layer 2541 is preferably in the range of 500 angstroms (Å) to 3000 Å. When the thickness is less than 500 Å, it is difficult for the channel to be uniform. When the thickness is more than 3000 Å, is the transistor may not have the desired thickness.

The ohmic contact layers 2631 and 2651 may be disposed on the semiconductor layer 2541. The source electrode 2731 may be disposed on the ohmic contact layer 2631. The drain electrode 2751 may be separated from the source electrode 2731 and may be disposed on the ohmic contact layer 2651. The gate insulating layer 240 may cover the semiconductor layer 2541, the source electrode 2731, and the drain electrode 2751. The gate electrode 2241 may overlap the semiconductor layer 2541 on the gate insulating layer 140. The passivation layer 280 protecting the gate electrode 2241 may be formed on the gate electrode 2241.

The infrared sensing transistor TrI may further include a light blocking film 2111 overlapping the semiconductor layer 2541. For example, the light blocking film 2111 may be disposed between the upper base substrate 210 and the semiconductor layer 2541, and may prevent the semiconductor layer 2541 from being exposed to visible rays. A blocking insulating layer 230 made of an insulating material, such as silicon nitride, may be formed between the light blocking film 2111 and the semiconductor layer 2541.

The light blocking film 2111 may include a material that blocks the visible rays received from outside the display panel. For example, the light blocking film 2111 may include an organic material or amorphous silicon including black pigments.

The light blocking film 2111 may block visible rays that are incident on the display panel from outside the display panel to thereby improve the signal-to-noise ratio (SNR), and to minimize a sensitivity of the semiconductor layer 2541, including the amorphous silicon-germanium, to visible rays, such that the influence of the visible rays may be efficiently prevented.

The readout transistor TrC may be connected to the infrared sensing transistor TrI is through an overpass 290 and a drain electrode 275C of the readout transistor TrC.

The readout transistor TrC may include a semiconductor layer 254C, ohmic contact layers 263C and 265C, a source electrode 273C, the drain electrode 275C, a gate insulating layer 240, and a gate electrode 224C.

The semiconductor layer 254C may be disposed on the upper base substrate 210, and may be made of amorphous silicon, amorphous silicon-germanium, or micro-crystalline silicon. In some cases, the semiconductor layer 254C may be made of two layers, including a lower layer formed of amorphous silicon and an upper layer formed of amorphous silicon-germanium or micro-crystalline silicon. In some cases, the semiconductor layer 254C may be made of two layers, including a lower layer of micro-crystalline silicon and an upper layer of amorphous silicon-germanium. The thickness of the semiconductor layer 254C is preferably in the range of 500 Å to 3000 Å. When the thickness is less than 500 Å, it is difficult for the channel to be uniform, and when the thickness is more than 3000 Å, the transistor may not have the desired thickness.

The ohmic contact layers 263C and 265C may be disposed on the semiconductor layer 254C. The source electrode 273C may be disposed on the ohmic contact layer 263C. The drain electrode 275C may be separated from the source electrode 273C and may be disposed on the ohmic contact layer 265C. The gate insulating layer 240 may be disposed on the semiconductor layer 254C, the source electrode 273C, and the drain electrode 275C. The gate electrode 224C may overlap the semiconductor layer 254C on the gate insulating layer 140. A passivation layer 280 protecting the gate electrode 224C may be formed on the gate electrode 224C.

The readout transistor TrC may further include a light blocking film 211C is overlapping the semiconductor layer 254C. For example, the light blocking film 211C may be disposed between the upper base substrate 210 and the semiconductor layer 254C, and may prevent the semiconductor layer 254C from being exposed to the visible rays. A blocking insulating layer 230 made of an insulating material, such as silicon nitride, may be formed between the light blocking film 211C and the semiconductor layer 254C.

The visible light sensing transistor TrV configured to sense visible rays may be disposed on the upper base substrate 210. At least one of the readout transistors TrC may be electrically connected to the visible light sensing transistor TrV and may be disposed in the same layer as the visible light sensing transistor TrV.

The visible light sensing transistor TrV may include a semiconductor layer 254V, ohmic contact layers 263V and 265V, a source electrode 273V, a drain electrode 275V, a gate insulating layer 240, and a gate electrode 224V.

The semiconductor layer 254V may be disposed on the upper base substrate 210, and may be made of amorphous silicon, amorphous silicon-germanium, or micro-crystalline silicon. In some cases, the semiconductor layer 254V may be made of two layers, including a lower layer formed of amorphous silicon and an upper layer formed on amorphous silicon-germanium or micro-crystalline silicon. In some cases, the semiconductor layer 254V may be made of two layers, including a lower layer of micro-crystalline silicon and an upper layer of amorphous silicon-germanium. The thickness of the semiconductor layer 254V is preferably in the range of 500 Å to 3000 Å. When the thickness is less than 500 Å, it is difficult for the channel to be uniform, and when the thickness is more than 3000 Å, the transistor may not be sufficiently down-sized.

The ohmic contact layers 263V and 265V may be disposed on the semiconductor is layer 254V. The source electrode 273V may be disposed on the ohmic contact layer 263V. The drain electrode 275V may be separated from the source electrode 273V and may be disposed on the ohmic contact layer 265V. The gate insulating layer 240 may be disposed on the semiconductor layer 254V, the source electrode 273V, and the drain electrode 275V. The gate electrode 224V may overlap the semiconductor layer 254V on the gate insulating layer 140. A passivation layer 280 protecting the gate electrode 224V may be formed on the gate electrode 224V.

A readout transistor TrC may be connected to the visible light sensing transistor TrV through the overpass 290 and through the drain electrode 275C.

A reflection controlling layer 220 may be disposed between the upper base substrate 210 and the blocking insulating layer 230. The reflection controlling layer 220 may be a transparent layer having relatively high refractive index. For example, the reflection controlling layer 220 may be a layer consisting of silicon nitride (SiNx), silicon oxide (SiOx), aluminum oxide (Al₂O₃), and/or titanium dioxide (TiO₂). The reflection controlling layer 220 may cause a destructive interference on reflected light corresponding to a portion of the sensing transistors TrI and TrV and a metal pattern to drive the sensing transistors TrI and TrV, so that total reflectance may be decreased. In addition, the reflection controlling layer 220 may control a wavelength of reflected light of the metal pattern. For example, by changing a material and/or thickness of the reflection controlling layer 220, reflectance according to wavelength may be adjusted. Accordingly, the reflection controlling layer 220 may help to filter certain wavelengths of reflected light based on the material and thickness configuration of the reflection controlling layer 220.

For example, in some cases, when the reflection controlling layer 220 includes is silicon nitride (Si3N4), the thickness of the reflection controlling layer 220 may be about 500 Å to 900 Å. In some cases, when the reflection controlling layer 220 includes silicon oxide (SiO2), the thickness of the reflection controlling layer 220 may be about 700 Å to 1300 Å. In some cases, when the reflection controlling layer 220 includes aluminum oxide (Al2O3), the thickness of the reflection controlling layer 220 may be about 600 Å to 1200 Å. In some cases, when the reflection controlling layer 220 includes titanium dioxide (TiO2), the thickness of the reflection controlling layer 220 may be about 400 Å to 800 Å.

The display panel may include a lower polarizer 12 disposed on the lower substrate 100 and an upper polarizer 22 disposed on the upper substrate 200. The intensity of light incident to the lower substrate 100 and the upper substrate 200 may be controlled by using the polarization characteristics of the lower polarizer 12 and the upper polarizer 22.

The display panel may further include a backlight unit 910 disposed under the lower substrate 100. The backlight unit 910 may include at least one infrared ray emitting member 920 and at least one visible ray emitting member 930. The infrared ray emitting member 920 and the visible ray emitting member 930 may be point light sources, such as light-emitting devices (LEDs). The infrared rays and the visible rays respectively emitted from the infrared ray emitting member 920 and the visible ray emitting member 930 may be orthogonally incident on the lower substrate 100.

The infrared ray emitting member 920 and the visible ray emitting member 930 may be uniformly distributed on the whole backlight unit 910 to provide the infrared rays and the visible rays to the entire backlight unit 910. The infrared ray emitting member 911 and the visible ray emitting member 912 may be alternately arranged, irregularly arranged, arranged in a predetermined ratio, or in any predetermined manner desired by the manufacturer of the display is panel.

Referring to FIG. 2, the infrared rays and the visible rays are generated in the backlight unit 910. The infrared rays sequentially pass through the lower polarizer 12, the lower substrate 100, the liquid crystal layer 3, the upper substrate 200, and the upper polarizer 22.

Similarly, the visible rays sequentially pass through the lower polarizer 12, the lower substrate 100, the liquid crystal layer 3, the upper substrate 200, and the upper polarizer 22. The visible rays may be changed to colored rays by the color filter 23 of the lower substrate 100.

Infrared rays provided from the backlight unit 910 may be used to detect an approaching first object T1, which may be a physical object, such as a stylus or finger of a user. When the first object T1 is close to the display panel, infrared rays emitted from the display panel are reflected by the first object T1. The reflected infrared rays may be incident to and detected by the infrared ray sensor TrI positioned in the upper substrate 200. In this manner, touch sensing for the first object T1 may be executed, and occurrence of physical contact with the first object T1, the position of the contact, and the shape and size of the first object T1 may be detected/determined.

When a grayscale level of the visible light emitted from the display panel is brighter than a grayscale level of the visible light incident on the display panel from outside the display panel, the visible light emitted from the display panel may be used for the image sensing under the image sensing for a second object T2 close to the display panel. For example, the visible light emitted from the display panel may be reflected by the second object T2. The reflected visible light may be incident on and detected by the visible ray sensor TrV positioned in the upper substrate 200. Accordingly, image sensing for the second object T2 may be executed, is and image information for the second object T2 (such as the position, the shape, the size, and the color) may be obtained.

After confirming the contact location of the second object T2 through touch sensing, the grayscale level of the visible light emitted from the display panel toward the contact location may be selectively changed such that the image sensing for the second object T2 may be further effectively executed. For example, when the grayscale level of the visible light emitted from the display panel is darker than the grayscale level of the visible ray incident on the display panel from outside the display panel, touch sensing using the infrared rays may be executed. The grayscale level of the visible rays emitted from the display panel toward the contact location of the second object T2 recognized through touch sensing is selectively brightened, making effective image sensing of the second object T2 possible.

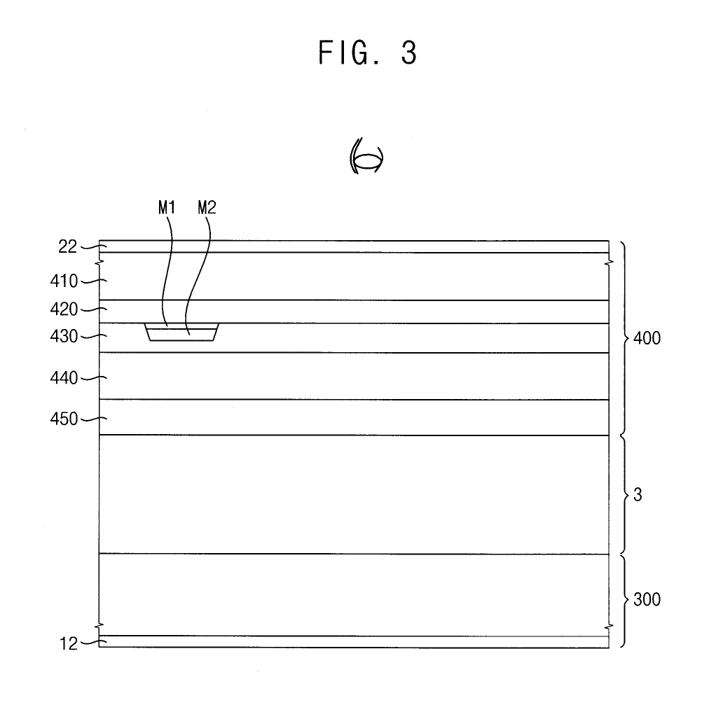

FIG. 3 is a cross-sectional view illustrating a display panel according to exemplary embodiments of the invention.

Referring to FIG. 3, the display panel may include a lower substrate 300, an upper substrate 400 facing the lower substrate 300, and a liquid crystal layer 3 between the lower substrate 300 and the upper substrate 400.

The display panel may be substantially similar to the display panel apparatus described hereinabove; however, the display panel apparatus described with respect to FIG. 3 includes metal pattern layers M1 and M2 and a reflection controlling layer 420. Thus, any further detailed descriptions concerning the same elements of the display panel will be omitted.

The upper substrate 400 may include an upper base substrate 410, the reflection controlling layer 420 disposed on the upper base substrate 410, the metal pattern layers M1 and M2 disposed on the reflection controlling layer 420, and an insulation layer 430 covering the is metal pattern layers M1 and M2 configured to insulate the metal pattern layers M1 and M2. The upper substrate 400 may further include a color filter layer 440 and protecting layer 450 protecting the color filter layer 440.

The metal pattern layers M1 and M2 may be a wiring pattern to drive a circuit element. For example, the metal pattern layers M1 and M2 may be a touch circuit sensing a touch (e.g., input) of a user, or a pixel circuit to display an image. The metal pattern layers M1 and M2 may include opaque metal. The metal pattern layers M1 and M2 may include a first metal pattern layer M1 disposed on the reflection controlling layer 420 and a second metal pattern layer M2 disposed on the first metal pattern layer M1. For example, the first metal pattern layer M1 may include titanium (Ti), and the second metal pattern layer M2 may include copper (Cu).

The reflection controlling layer 420 may be a transparent layer having relatively high refractive index. For example, the reflection controlling layer 420 may include silicon nitride (SiNx), silicon oxide (SiOx), aluminum oxide, and/or titanium dioxide (TiO₂). The reflection controlling layer 420 may cause a destructive interference to light reflected from a portion of the metal pattern layer M1 and M2, so that total reflectance may be decreased. In addition, the reflection controlling layer 420 may control reflection of the metal pattern layer M1 and M2. For example, by changing the material and thickness of the reflection controlling layer 420, reflectance at determined wavelengths may be adjusted.

For example, when the reflection controlling layer 420 includes silicon nitride (Si3N4), the thickness of the reflection controlling layer 420 may be about 500 Å to 900 Å. When the reflection controlling layer 420 includes silicon oxide (SiO2), the thickness of the reflection controlling layer 420 may be about 700 Å to 1300 Å. When the reflection controlling is layer 420 includes aluminum oxide (Al2O3), the thickness of the reflection controlling layer 420 may be about 600 Å to 1200 Å. When the reflection controlling layer 420 includes titanium dioxide (TiO2), the thickness of the reflection controlling layer 420 may be about 400 Å to 800 Å.

The display panel may include a lower polarizer 12 disposed under the lower substrate 300 and an upper polarizer 22 disposed on the upper substrate 400.

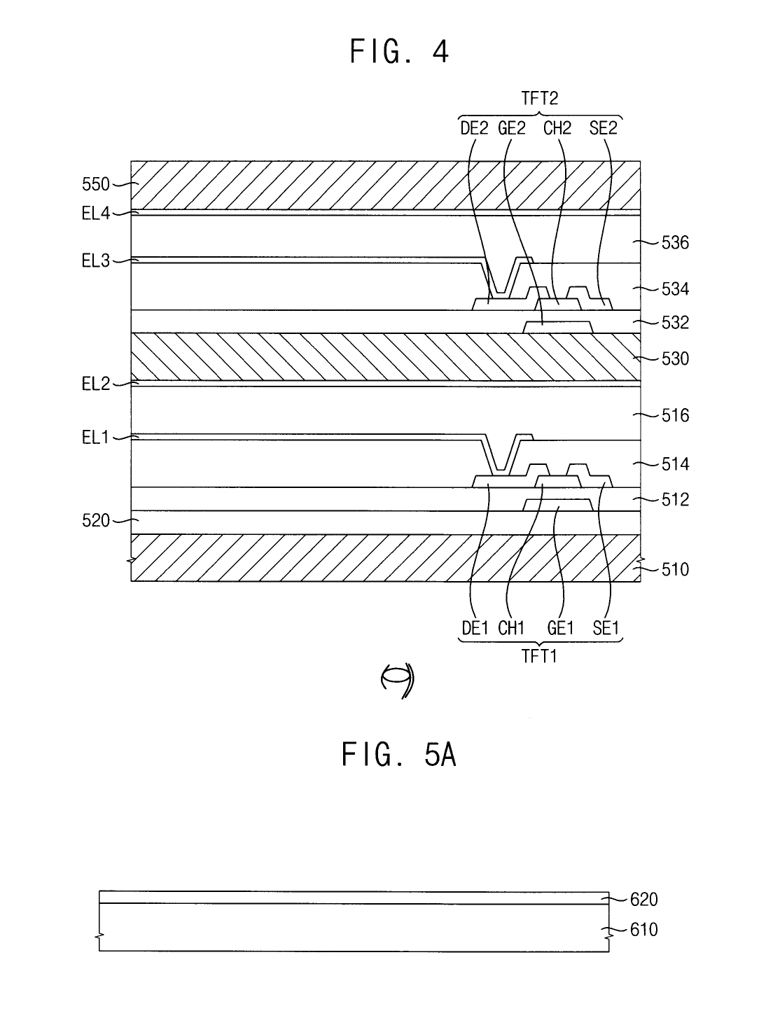

FIG. 4 is a cross-sectional view illustrating a display panel according to exemplary embodiments of the invention.

Referring to FIG. 4, the display panel includes a first substrate 510, a reflection controlling layer 520, a first switching element TFT1, a first insulation layer 512, a second insulation layer 514, a first electrode EL1, a color displaying layer 516, a second electrode EL2, a second substrate 530, a second switching element TFT2, a third insulation layer 532, a fourth insulation layer 534, a third electrode EL3, a color conversion layer 536, a fourth electrode EL4, and a third substrate 550. The display panel of FIG. 4 may be used for a transparent display apparatus.

The first substrate 510 may be made of a transparent glass or plastic.

The first switching element TFT1 may include a first gate electrode GE1 disposed on the first substrate 510, a first channel layer CH1 disposed above the first gate electrode GE1 on the first insulation layer 512 and overlapping the first gate electrode GE1, a first source electrode SE1 connected to the first channel layer CH1, and a first drain electrode DE1 connected to the first channel layer CH1 and spaced apart from the first source electrode SE1. The first insulation layer 512 may be disposed between the first gate electrode GE1 and the first channel layer CH1. The second insulation layer 514 may be disposed on the first switching is element TFT1 to cover the first switching element TFT1.

The reflection controlling layer 520 is disposed between the first switching element TFT1 and the first substrate 510.

The reflection controlling layer 520 may be a transparent layer having relatively high refractive index. For example, the reflection controlling layer 520 may include silicon nitride (SiNx), silicon oxide (SiOx), aluminum oxide, and/or titanium dioxide (TiO₂). The reflection controlling layer 520 may cause a destructive interference to reflected light from metal wiring of the first switching element TFT1, so that a total reflectance may be decreased. In addition, the reflection controlling layer 520 may control a reflection of the metal pattern. For example, by changing the material and thickness of the reflection controlling layer 520, the reflectance at determined wavelengths may be adjusted.

For example, when the reflection controlling layer 520 includes silicon nitride (Si3N4), the thickness of the reflection controlling layer 520 may be about 500 Å to 900 Å. When the reflection controlling layer 520 includes silicon oxide (SiO₂), the thickness of the reflection controlling layer 520 may be about 700 Å to 1300 Å. When the reflection controlling layer 520 includes aluminum oxide (Al2O3), the thickness of the reflection controlling layer 520 may be about 600 Å to 1200 Å. When the reflection controlling layer 520 includes titanium dioxide (TiO2), the thickness of the reflection controlling layer 520 may be about 400 Å to 800 Å.

The first electrode EL1 electrically connected to the first switching element TFT1 may be formed on the second insulation layer 514. The first electrode EL1 may include transparent conductive material. For example, the first electrode EL1 may include indium tin oxide (ITO) or indium zinc oxide (IZO). In some cases, the first electrode EL1 may include is titanium (Ti) or molybdenum-titanium alloy (MoTi).

The color displaying layer 516 may include cholesteric liquid crystal, and may be formed on the first electrode EL1. In some cases, the cholesteric liquid crystal may have a spiral structure in which molecules arranged in each layer are spirally twisted while forming a layered structure similar to a smectic liquid crystal such that the color displaying layer 516 may have a memory characteristic, a high contrast ratio, and a high resolution characteristic. In some cases, the cholesteric liquid crystal may have a planar state in which light at a specific wavelength may be reflected, a focal conic state in which light may be transmitted, or a middle state thereof, and a characteristic that the cholesteric liquid crystal maintains the specific state even if a voltage is not applied. The material comprising the cholesteric liquid crystal may include a cholesterol derivative. A composition in which an optical activated radical, such as a 2-methyl-butyl group and a 2-methyl-butoxy group, may be added to the common nematic liquid crystal material.

In some cases, the cholesteric liquid crystal may be divided into a plurality of cells, and the cells may respectively display a white color or one of a plurality of primary colors. The color of the cells may be the same or different from adjacent cells. The color of the cells may include, for example, red, green, and blue, or yellow, magenta, and cyan, or various other colors.

The second electrode EL2 is disposed on the color displaying layer 516. The second electrode EL2 may include transparent conductive material. For example, the first electrode EL2 may include indium tin oxide (ITO) or indium zinc oxide (IZO). In some cases, the second electrode EL2 may include titanium (Ti) or molybdenum-titanium alloy (MoTi).

The second substrate 530 is disposed on the second electrode EL2. The second substrate 530 may be made of a transparent glass or plastic.

The second switching element TFT2 may include a second gate electrode GE2 disposed on the second substrate 530, a second channel layer CH2 disposed above the second gate electrode GE2 and overlapping the second gate electrode GE2, a second source electrode SE2 connected to the second channel layer CH2, and a second drain electrode DE2 connected to the second channel layer CH2 and spaced apart from the second source electrode SE2. The third insulation layer 532 may be disposed between the second gate electrode GE2 and the second channel layer CH2. The fourth insulation layer 534 may be disposed on the second switching element TFT2 to cover the second switching element TFT2.

The third electrode EL3 electrically connected to the second switching element TFT2 may be disposed on the fourth insulation layer 534. The third electrode EL3 may include transparent conductive material. For example, the third electrode EL3 may include indium tin oxide (ITO) or indium zinc oxide (IZO). In some cases, the third electrode EL3 may include titanium (Ti) or molybdenum-titanium alloy (MoTi).

The color conversion layer 536 may include an electrochromic organic or inorganic material or a reverse emulsion based on an electrophoretic display, and may be deposited on the second switching element TFT2.

In some cases, when the color conversion layer 536 includes the electrochromic display, the color conversion layer 536 may reversibly change a color of the electrochromic material according to an electric field direction when a voltage is applied across the electrochromic material. The electrochromic material may have an optical characteristic that is reversibly changed by an oxidation and reduction reaction. An electrochromic inorganic material, such as tungsten trioxide (WO₃), Molybdenum trioxide (MoO₃), and Titanium trioxide (TiO₃), may have a cathodic coloration in which a color is represented in a reduction state and is the color disappears in an oxidation state. An electrochromic inorganic material, such as Vanadium Oxide (V₂O₅), Iridium Oxide (IrO₂), Niobium Oxide (Nb₂O₅), and Nickel Oxide (NiO), may have an anodic coloration in which the color disappears in the reduction state and the color appears in the oxidation state. Electrochromic organic materials, such as a viologen derivative, exist.

In some cases, the color conversion layer 536 may include a plurality of divided cells. The divided cells may be transparent in a non-chroma state, and may be black-colored in an opaque state, or may display an ash color gradation between the non-chroma and the opaque states. The color of the cells may be the same or different. The electrochromic material may have light transmittance characteristics according to an applied voltage level. For example, the electrochromic material may be changed in color such as opaque black, the semi-transparent ash color, and the transparent non-chroma state. The electrochromic display or the electrophoretic display does not need a polarizer and, in some cases, may use a material having a memory function.

The fourth electrode EL4 may be disposed on the color conversion layer 536. The fourth electrode EL4 may include transparent conductive material. For example, the fourth electrode EL4 may include indium tin oxide (ITO) or indium zinc oxide (IZO). In some cases, the fourth electrode EL4 may include titanium (Ti) or molybdenum-titanium alloy (MoTi).

The third substrate 550 is disposed on the fourth electrode EL4. The third substrate 550 may be made of a transparent glass or plastic.

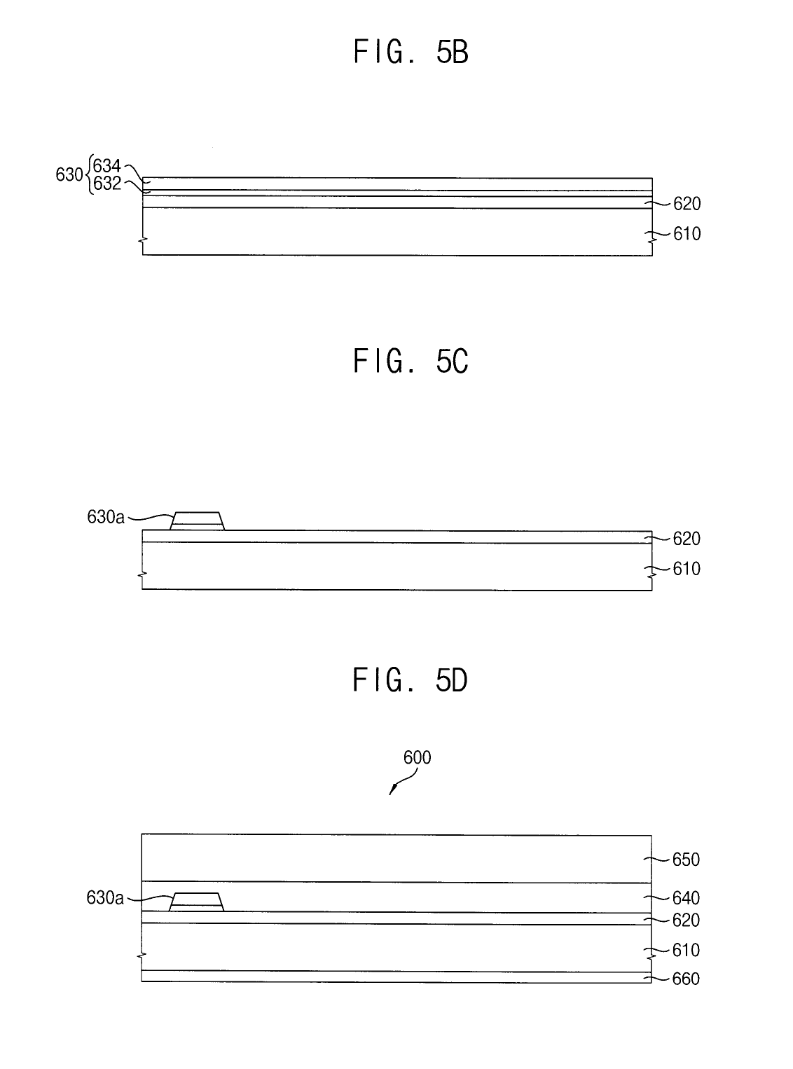

FIGS. 5A, 5B, 5C, and 5D are cross-sectional views illustrating a method of manufacturing a display panel according to exemplary embodiments of the invention.

Referring to FIG. 5A, a reflection controlling layer 620 may be formed on a is substrate 610. The substrate 610 may be made of a transparent glass or plastic. The reflection controlling layer 620 may be a transparent layer having relatively high refractive index. For example, the reflection controlling layer 620 may include silicon nitride (SiNx), silicon oxide (SiOx), aluminum oxide, and/or titanium dioxide (TiO₂). The material and thickness of the reflection controlling layer 620 may be adjusted to configure the wavelength of reflected light from a metal pattern (refers to 630a of FIG. 5C).

For example, when the metal pattern includes copper (Cu) or copper and titanium (Ti) and the reflection controlling layer 620 includes silicon nitride (Si3N4), a thickness of the reflection controlling layer 620 may be about 500 Å to 900 Å. Accordingly, light having a red color wavelength (about 650 to 800 Å), which is mainly reflected on the metal pattern, may be reduced compared to light having other wavelengths by using destructive interference. Thus, reflected light having a red color wavelength, which may be unpleasant for a user/viewer, may be decreased.

When the metal pattern includes copper (Cu) or copper and titanium (Ti) and the reflection controlling layer 620 includes silicon oxide (SiO2), a thickness of the reflection controlling layer 620 may be about 700 Å to 1300 Å. When the metal pattern includes copper (Cu) or copper and titanium (Ti) and the reflection controlling layer 620 includes aluminum oxide (Al2O3), a thickness of the reflection controlling layer 620 may be about 600 Å to 1200 Å. When the metal pattern includes copper (Cu) or copper and titanium (Ti) and the reflection controlling layer 620 includes titanium dioxide (TiO2), a thickness of the reflection controlling layer 620 may be about 400 Å to 800 Å.

Referring to FIG. 5B, a metal layer 630 may be disposed on the reflection controlling layer 620. The metal layer 630 may include a first metal layer 632 disposed on the is reflection controlling layer 620, and a second metal layer 634 disposed on the first metal layer 632. The first metal layer 632 may include titanium (Ti) and may have thickness of about 200 Å. The second metal layer 634 may include copper (Cu) and may have a thickness of about 3000 Å.

Referring to FIG. 5C, the metal layer 630 may be patterned into a metal pattern 630a. For example, a photoresist composition may be coated on the metal layer 630, and a photoresist pattern corresponding to the metal pattern 630a may be formed. Thereafter, a portion of the metal layer 630, which is not covered by the photoresist pattern, may be etched thereby forming the metal pattern 630a.

Referring to FIG. 5D, an insulation layer 640 may be disposed on the metal layer 630. A specific layer 650 may be further disposed on the insulation layer 640. For example, a protecting layer, a liquid crystal layer, another insulation layer or a substrate may be further disposed on the insulation layer 640.

A polarizer 660 may be further disposed under the substrate 610. A user or viewer may see an image displayed on the display panel through the polarizer 660. Light passes the polarizer 660, the substrate 610, and the reflection controlling layer 620. Thereafter, the light is reflected on a surface of the metal pattern 630a, and received by the viewer's eyes. A wavelength of the reflected light may be controlled by destructive interference of the reflection controlling layer 620. Thus, reflected light having a red color wavelength, which is unpleasant for the viewer, may be decreased.

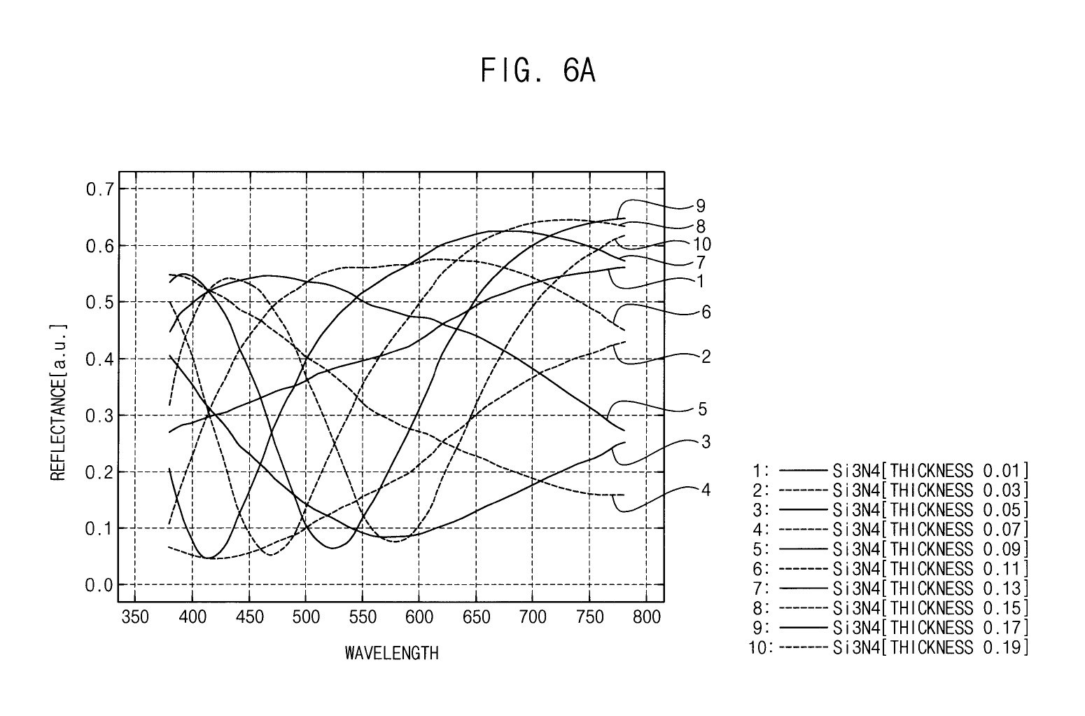

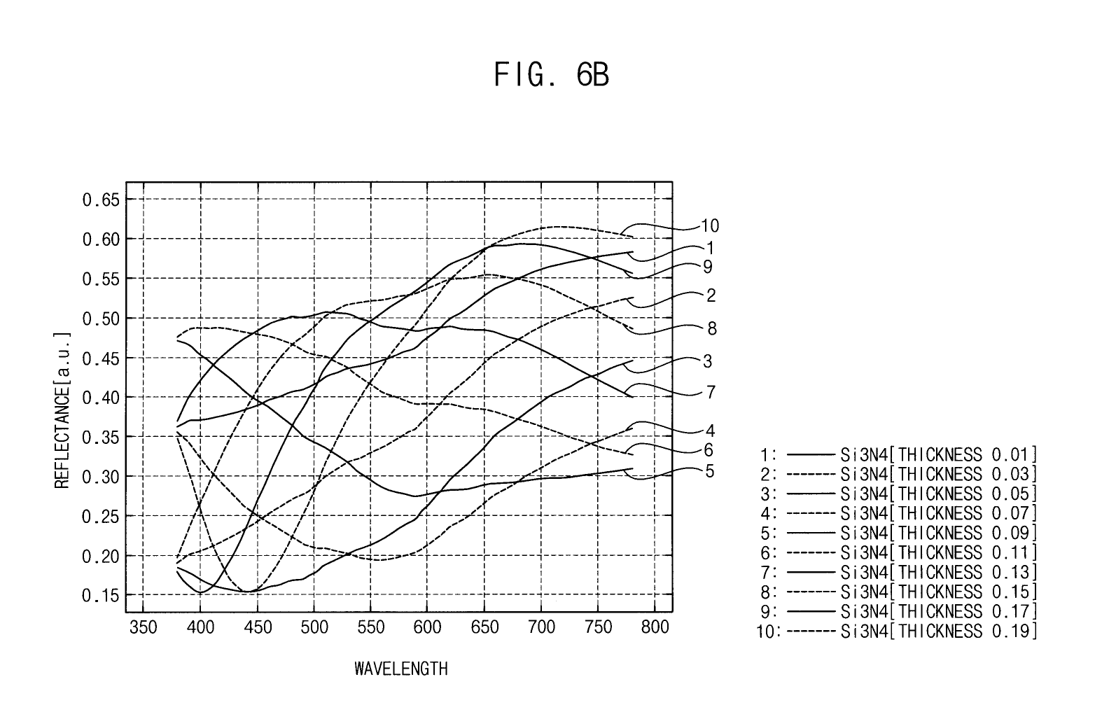

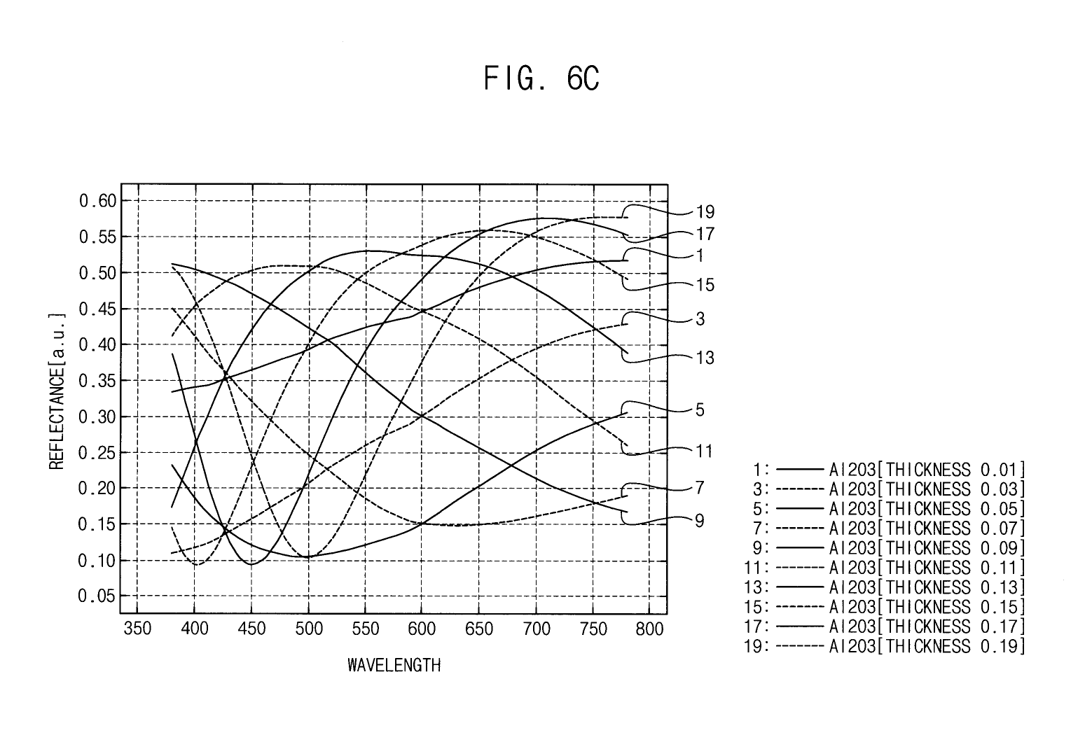

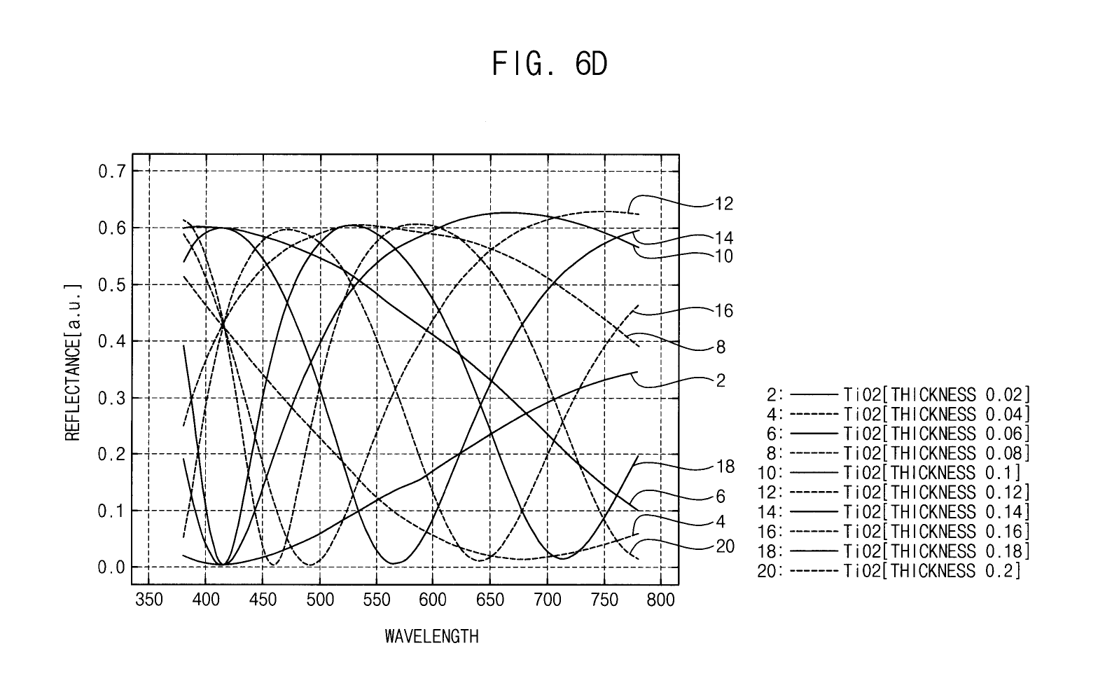

FIGS. 6A, 6B, 6C, and 6D are graphs illustrating reflectance according to a wavelength of light reflected from a display panel according to exemplary embodiments of the invention.

Referring to FIGS. 6A, 6B, 6C, and 6D, the graphs illustrate a reflectance of light is from a metal layer according to wavelength and according to a thickness of a reflection controlling layer.

Referring again to FIG. 6A, a display panel may include a reflection controlling layer 420 and metal wiring layers M1 and M2 as shown in FIG. 3.

When the metal pattern includes copper (Cu) or copper and titanium (Ti) and the reflection controlling layer includes silicon nitride (Si3N4), generally, reflected light may have a red color wavelength (about 650 Å to 800 Å) stronger than other color wavelengths, because reflectance of red color wavelength is higher than that of other color wavelengths due to the metal pattern having copper. Thus, a viewer may undesirably and problematically see red colored reflected light from the metal pattern. As described in FIG. 6A, when the reflection controlling layer has thickness of 700 Å, reflectance of red color wavelength is remarkably decreased. Considering process margin and reflection controlling effect, when the reflection controlling layer includes silicon nitride, the thickness of the reflection controlling layer may preferably be about 500 Å to 900 Å.

Referring to FIG. 6B, when the metal pattern includes copper (Cu) or copper and titanium (Ti) and the reflection controlling layer includes silicon oxide (SiO2), generally, reflected light may have a red color wavelength (about 650 Å to 800 Å) stronger than other color wavelengths, because reflectance of red color wavelength is higher than that of other color wavelengths due to the metal pattern having copper. Thus, a viewer may undesirably and problematically see red colored reflected light from the metal pattern. As described in FIG. 6B, when the reflection controlling layer has a thickness of 1000 Å, reflectance of red color wavelength is remarkably decreased. Considering process margin and reflection controlling effect, when the reflection controlling layer includes silicon oxide, the thickness of the reflection is controlling layer may preferably be about 700 Å to 1300 Å.

Referring to FIG. 6C, when the metal pattern includes copper (Cu) or copper and titanium (Ti) and the reflection controlling layer includes aluminum oxide (Al2O3), generally, reflected light may have a red color wavelength (about 650 Å to 800 Å) stronger than other color wavelengths, because reflectance of red color wavelength is higher than that of other color wavelengths due to the metal pattern having copper. Thus, a viewer may undesirably and problematically see red colored reflected light from the metal pattern. As described in FIG. 6C, when the reflection controlling layer has a thickness of 900 Å, reflectance of red color wavelength is remarkably decreased. Considering process margin and reflection controlling effect, when the reflection controlling layer includes aluminum oxide, the thickness of the reflection controlling layer may preferably be about 600 Å to 1200 Å.

Referring to FIG. 6D, when the metal pattern includes copper (Cu) or copper and titanium (Ti) and the reflection controlling layer includes titanium dioxide (TiO2), generally, reflected light may have a red color wavelength (about 650 Å to 800 Å) stronger than other color wavelengths, because reflectance of red color wavelength is higher than that of other color wavelengths due to the metal pattern having copper. Thus, a viewer may undesirably and problematically see red colored reflected light from the metal pattern. As described in FIG. 6D, when the reflection controlling layer has a thickness of 600 Å, reflectance of red color wavelength is remarkably decreased. Considering process margin and reflection controlling effect, when the reflection controlling layer includes titanium dioxide, the thickness of the reflection controlling layer may preferably be about 400 Å to 800 Å.

As can be appreciated from the foregoing, a thickness of the reflection controlling layer materials may be configured to minimize red colored reflected light and reflectance is according to the wavelength of the reflected light. The reflected light may be controlled using destructive interference by changing a material and thickness of the reflection controlling layer.

According to the exemplary embodiments of the present invention, the display panel may include a metal wiring layer and a reflection controlling layer disposed between the metal wiring layer and a base substrate, so that total reflectance may be decreased according to destructive interference to light reflected from the metal wiring.

In addition, by changing the material and thickness of the reflection controlling layer, reflectance according to wavelength may be configured to reduce colored reflected light that may be unpleasant to a viewer/user.

It will be apparent to those skilled in the art that various modifications and variations can be made without departing from the spirit or scope of the invention. Thus, it is intended that the present invention cover the modifications and variations of this invention provided they come within the scope of the appended claims and their equivalents.

What is claimed is:

1. A display substrate, comprising:
a base substrate;
a reflection controlling layer disposed on the base substrate; and
a metal wiring layer disposed on the reflection controlling layer and comprising an opaque metal, the reflection controlling layer being configured to provide a reflectance of reflected light corresponding to a wavelength using destructive interference, the reflected light being reflected from the metal wiring layer through the base substrate and the reflection controlling layer.

2. The display substrate of claim 1, wherein the metal wiring layer comprises:
a first metal wiring layer comprising titanium; and
a second metal wiring layer disposed on the first metal wiring layer and comprising copper.

3. The display substrate of claim 2, wherein the metal wiring layer is a portion of a sensing switching element, and the metal wiring layer comprises a wiring configured to drive the sensing switching element.

4. The display substrate of claim 2, wherein the sensing switching element comprises an infrared sensing switching element and a visible light sensing switching element,
wherein the infrared sensing switching element comprises:
a first semiconductor layer comprising amorphous silicon-germanium or micro-crystalline silicon;
a first ohmic contact layer disposed on the first semiconductor layer;
a first source electrode disposed on the first ohmic contact layer;
a first drain electrode disposed on the first ohmic contact layer and spaced apart the first source electrode; and
a light blocking film overlapping the first semiconductor layer and comprising organic material or amorphous silicon comprising black pigments, and
wherein the visible light sensing switching element comprises:
a second semiconductor layer comprising amorphous silicon-germanium or micro-crystalline silicon;
a second ohmic contact layer disposed on the second semiconductor layer;
a second source electrode disposed on the second ohmic contact layer; and
a second drain electrode disposed on the second ohmic contact layer and spaced apart from the second source electrode.

5. The display substrate of claim 1, wherein the reflection controlling layer comprises one of silicon nitride, silicon oxide, aluminum oxide, and titanium dioxide, and
if the reflection controlling layer comprises the silicon nitride, a thickness of the reflection controlling layer is about 500 angstroms (Å) to 900 Å,
if the reflection controlling layer comprises the silicon oxide, the thickness of the reflection controlling layer is about 700 Å to 1300 Å,
if the reflection controlling layer comprises the aluminum oxide, the thickness of the reflection controlling layer is about 600 Å to 1200 Å, and
if the reflection controlling layer comprises the titanium dioxide, the thickness of the reflection controlling layer is about 400 Å to 800 Å.

6. The display substrate of claim 1, wherein the metal wiring layer comprises a touch circuit configured to detect an input or a pixel circuit configured to display an image.

7. The display substrate of claim 1, wherein the metal wiring layer comprises copper.

8. The display substrate of claim 1, further comprising an upper polarizer disposed under the base substrate, wherein the reflected light may be reflected from the metal wiring layer through the upper polarizer, the base substrate, and the reflection controlling layer.

9. The display substrate of claim 1, wherein the metal wiring layer is a portion of a first switching element and the metal wiring layer comprises a wiring configured to drive the first switching element, and
wherein the display substrate further comprises:
a first electrode connected to the first switching element;
a color displaying layer disposed on the first electrode and comprising cholesteric liquid crystal;
a second electrode disposed on the color displaying layer;
a second substrate disposed on the second electrode;
a second switching element disposed on the second substrate;
a third electrode connected to the second switching element;
a color conversion layer disposed on the third electrode and comprising electrochromic material or reverse emulsion based on an electrophoretic display;
a fourth electrode disposed on the color conversion layer; and
a third substrate disposed on the fourth electrode.

10. A display panel, comprising:
an upper substrate;
a lower substrate facing the upper substrate; and
a liquid crystal layer disposed between the upper substrate and the lower substrate,
wherein the upper substrate comprises:
an upper base substrate;
a reflection controlling layer disposed on the upper base substrate;
a metal wiring layer disposed on the reflection controlling layer; and
a first insulation layer disposed on the metal wiring layer,
wherein the lower substrate comprises:
a lower base substrate;
a pixel switching element disposed on the lower base substrate; and
a second insulation layer disposed on the pixel switching element, and
wherein the liquid crystal layer is disposed between the first insulation layer and the is second insulation layer, the reflection controlling layer being configured to provide a reflectance of reflected light corresponding to a wavelength using destructive interference, the reflected light being reflected from the metal wiring layer through the base substrate and the reflection controlling layer.

11. The display panel of claim 10, wherein the reflection controlling layer comprises one of silicon nitride, silicon oxide, aluminum oxide, and titanium dioxide, and
if the reflection controlling layer comprises the silicon nitride, a thickness of the reflection controlling layer is about 500 angstroms(Å) to 900 Å,
if the reflection controlling layer comprises the silicon oxide, the thickness of the reflection controlling layer is about 700 Å to 1300 Å,
if the reflection controlling layer comprises the aluminum oxide, the thickness of the reflection controlling layer is about 600 Å to 1200 Å, and
if the reflection controlling layer 220 comprises the titanium dioxide, the thickness of the reflection controlling layer is about 400 Å to 800 Å.

12. The display panel of claim 10, further comprising a lower polarizer disposed under the lower base substrate and an upper polarizer disposed under the upper base substrate,
wherein reflected light is reflected from the metal wiring layer through the upper polarizer, the upper base substrate, and the reflection controlling layer.

13. The display panel of claim 10, wherein the metal wiring layer comprises copper.

14. The display panel of claim 10, wherein the metal wiring layer comprises:
a first metal wiring layer comprising titanium; and
a second metal wiring layer disposed on the first metal wiring layer and comprising copper.

15. The display panel of claim 10, wherein the metal wiring layer is a portion of an infrared sensing switching element, and the metal wiring layer comprises a wiring configured to drive the infrared sensing switching element.

16. The display panel of claim 15, wherein the infrared sensing switching element comprises:
a semiconductor layer comprising amorphous silicon-germanium or micro-crystalline silicon;
an ohmic contact layer disposed on the semiconductor layer;
a source electrode disposed on the ohmic contact layer;
a drain electrode disposed on the ohmic contact layer and spaced apart from the source electrode; and
a light blocking film overlapping the semiconductor layer and comprising organic material or amorphous silicon comprising black pigments.

17. A display apparatus, comprising:
a display panel comprising an upper substrate, a lower substrate facing the upper substrate, and a liquid crystal layer disposed between the upper substrate and the lower substrate; and
a backlight unit configured to provide light to the display panel,
wherein the upper substrate comprises:
an upper base substrate;
a reflection controlling layer disposed on the upper base substrate;
a metal wiring layer disposed on the reflection controlling layer; and
a first insulation layer disposed on the metal wiring layer,
wherein the lower substrate comprises:
a lower base substrate;
a pixel switching element disposed on the lower base substrate; and
a second insulation layer disposed on the pixel switching element, and
wherein the liquid crystal layer is disposed between the first insulation layer and the second insulation layer, the reflection controlling layer being configured to provide a reflectance of reflected light corresponding to a wavelength using destructive interference, the reflected light being reflected from the metal wiring layer through the base substrate and the reflection controlling layer.

18. The display apparatus of claim 17, wherein the metal wiring layer is a portion of a sensing switching element, and the metal wiring layer comprises a wiring configured to drive the sensing switching element,
wherein the sensing switching element comprises an infrared sensing switching element and a visible light sensing switching element,
wherein the infrared sensing switching element comprises:
a first semiconductor layer comprising amorphous silicon-germanium or micro-crystalline silicon;
a first ohmic contact layer disposed on the first semiconductor layer;
a first source electrode disposed on the first ohmic contact layer;
a first drain electrode disposed on the first ohmic contact layer and spaced apart from the first source electrode; and
a light blocking film overlapping the first semiconductor layer and comprising organic material or amorphous silicon comprising black pigments, and
wherein the visible light sensing switching element comprises:
a second semiconductor layer comprising amorphous silicon-germanium or micro-crystalline silicon;
a second ohmic contact layer disposed on the second semiconductor layer;
a second source electrode disposed on the second ohmic contact layer; and
a second drain electrode disposed on the second ohmic contact layer and spaced apart from the source electrode; and
wherein the backlight unit comprises an infrared ray emitting member and a visible ray emitting member.

19. The display apparatus of claim 17, wherein the reflection controlling layer comprises one of silicon nitride, silicon oxide, aluminum oxide, and titanium dioxide, and
if the reflection controlling layer comprises the silicon nitride, a thickness of the reflection controlling layer 220 is about 500 angstroms (Å) to 900 Å,
if the reflection controlling layer comprises the silicon oxide, the thickness of the reflection controlling layer is about 700 Å to 1300 Å,
if the reflection controlling layer comprises the aluminum oxide, the thickness of the reflection controlling layer is about 600 Å to 1200 Å, and
if the reflection controlling layer 220 comprises titanium dioxide, the thickness of the reflection controlling layer is about 400 Å to 800 Å.

20. A method of manufacturing a display substrate, the method comprising:
forming a reflection controlling layer on a substrate;
forming a metal layer on the reflection controlling layer;
forming a metal wiring by patterning the metal layer; and
forming an insulation layer on the metal wiring,
wherein the reflection controlling layer comprises one of silicon nitride, silicon oxide, aluminum oxide, and titanium dioxide, and
if the reflection controlling layer comprises the silicon nitride, a thickness of the reflection controlling layer 220 is about 500 (angstroms) A to 900 Å,
if the reflection controlling layer comprises the silicon oxide, the thickness of the reflection controlling layer is about 700 Å to 1300 Å,
if the reflection controlling layer comprises the aluminum oxide, the thickness of the reflection controlling layer is about 600 Å to 1200 Å, and
if the reflection controlling layer 220 comprises the titanium dioxide, the thickness of the is reflection controlling layer is about 400 Å to 800 Å.
